(19) United States
(12) Patent Application Publication
(10) Pub. No.: US 2009/0084403 A1
(43) Pub. Date: Apr. 2, 2009

(54) SUBSTRATE CLEANING APPARATUS, SUBSTRATE PROCESSING APPARATUS, SUBSTRATE CLEANING METHOD, SUBSTRATE PROCESSING METHOD AND STORAGE MEDIUM

(75) Inventor: Takehiro Shindo, Yamanashi (JP)

Correspondence Address: PEARNE & GORDON LLP, 1801 EAST 9TH STREET, SUITE 1200, CLEVELAND, OH, 44114-3108, US

(73) Assignee: TOKYO ELECTRON LIMITED, Tokyo (JP)

(21) Appl. No.: 12/235,740

(22) Filed: Sep. 23, 2008

(30) Foreign Application Priority Data
Sep. 28, 2007 (JP) 2007-255978

(51) Int. Cl. B08B 1/00; B08B 11/02; H01L 21/67

(52) U.S. Cl. 134/6; 134/25.4; 15/102; 15/103.5

(57) ABSTRACT

A deposit adhered to a rear surface peripheral portion of a substrate is easily and reliably removed, and a cycle of maintenance such as an exchange or a cleaning of a member required for removing the deposit is extended. An outer peripheral surface of a first cleaning rotational body having a roughly cylindrical shape has an adhesive property, and is brought into contact with a substrate from its side surface to its rear surface peripheral portion. Further, an outer peripheral surface of a second cleaning rotational body, which has an adhesive property stronger than that of the outer peripheral surface of the first cleaning rotational body, is brought into contact with the outer peripheral surface of the first cleaning rotational body, and the substrate, the first cleaning rotational body and the second cleaning rotational body are integrally rotated.

### FIELD OF THE INVENTION

The present disclosure relates to a technology of removing a deposit adhered to a peripheral portion of a rear surface of a circular-shaped substrate, e.g., a semiconductor wafer.

### BACKGROUND OF THE INVENTION

Among semiconductor manufacturing apparatuses, there is an apparatus for performing an etching process using plasma or an apparatus for performing a film forming process using a film forming gas, on a semiconductor wafer (hereinafter, referred to as a ‘wafer’). In order to prevent a peripheral portion of the wafer from being chipped or broken, a bevel process has been performed on the wafer. When a process is performed in this kind of apparatus, a gas is introduced into a rear surface of a bevel portion of the peripheral portion of the wafer, so that a reaction product is adhered thereto. For example, in an etching apparatus using plasma, since a focus ring is disposed close to a peripheral portion of a wafer to surround the wafer in order to adjust a state of plasma, the peripheral portion of the wafer is protruded slightly from a mounting table. Accordingly, a reaction product, which is generated by a reaction between an etching gas and an etching target portion and then is floated in an atmosphere, is also adhered to a rear surface of a bevel portion of the wafer. Further, in a film forming apparatus, typically, a whole wafer is disposed on a mounting table, but a bevel portion is positioned away from a mounting surface so that a film is adhered on the bevel portion.

The deposit adhered to the bevel portion of the wafer easily comes off from a bent portion of an inner end or an outer end of the bevel portion, so that this easily becomes a cause for a particle contamination of the wafer. As a result, this becomes one of causes for a decrease in a production yield. Further, the problem as stated above occurs not only in a vacuum processing apparatus but also in case of coating a photoresist on a surface of a wafer, because a coating solution is introduced into a rear surface of a bevel portion. Furthermore, the problem as stated above also occurs in a process of forming a mask pattern not only on the wafer having the bevel portion but also on, e.g., a circular-shaped glass substrate serving as a mask used during an exposure process.

As a method of removing such deposit, there has been known, for example, a technique of cleaning a substrate using a wet method by providing a cleaning solution to the substrate, but it is difficult to adopt the wet method in the above-mentioned vacuum processing apparatus. Also, there is cost for preparing a solvent and a liquid drain apparatus is also required, so that running cost increases. Accordingly, a technique of removing the deposit using a dry method has been studied.

Patent Document 1 discloses a technique of removing a deposit using a chemical method by supplying a reactant gas to a peripheral portion of a substrate and heating the peripheral portion. However, with this method, there is a need for selecting a kind of reactant gas according to a composition of the deposit, and also, it is impossible to remove the deposit if a reactivity of the deposit is very low.

For this reason, by combining such chemical method with a physical method, the removal of the deposit is performed. That is, for example, there has been known a method of removing a deposit by bringing a rotating brush into contact with a peripheral portion of a substrate, and then rotating the rotating brush and also rotating the substrate. However, with this method, there is a need for a local gas exhaust unit for sucking in a floating deposit separated from the substrate by the brush. In addition, even though such a local gas exhaust unit is operated, it is impossible to entirely discharge the deposit, so there is a likelihood that the deposit removed from a rear surface of the substrate adheres to a front surface of the substrate. Further, there is a need for maintenance of frequently removing the deposit adhered to the brush. Furthermore, with such a brush, it is very difficult to bring the brush into contact with only a side surface of the substrate, a bevel portion or the peripheral portion of the rear surface of the substrate, which is the portion where the deposit should be removed. If the brush makes contact with the front surface of the substrate, there is a likelihood that a defect is made on a device, thereby causing a decrease in a production yield.

Patent Document 2 discloses a technique of removing a minute particle adhered to a substrate by bringing an adhesive sheet into contact with a rear surface or a bevel portion of the substrate. However, with this method, the used amount of the adhesive sheet increases, so that running cost increases. In addition, when removing the minute particle adhered to the bevel portion, the amount of the adhesive sheet wasted without making contact with the bevel portion increases, so that it is not desirable in an economical or environmental aspect.
Patent Document 1: Japanese Patent Laid-open Application No. 2006-287169 (See Paragraphs 0052 to 0055)
Patent Document 2: Japanese Patent Laid-open Application No. 2002-83795 (See Paragraphs 0060 to 0063 and FIGS. 7 and 8)

### BRIEF SUMMARY OF THE INVENTION

In view of the foregoing, the present disclosure provides a technique of reliably and easily removing a deposit adhered to a rear surface peripheral portion of a circular-shaped substrate.

In accordance with an aspect of the present disclosure, there is provided a substrate cleaning apparatus for cleaning a rear surface peripheral portion of a circular-shaped substrate, the apparatus including: a substrate holding unit, which is rotatable, for adsorbing and holding a center portion rather than the rear surface peripheral portion of the substrate and rotating a center of the substrate as a rotational center; a first cleaning rotational body which is rotated together with the substrate while making contact with the rear surface peripheral portion of the substrate and is configured such that an outer peripheral surface thereof is an adhesive surface; a driving unit for rotating at least one of the substrate holding unit and the first cleaning rotational body; and a second cleaning rotational body which is rotated while making contact with the outer peripheral surface of the first cleaning rotational body and is configured such that an outer peripheral surface thereof is an adhesive surface having an adhesive force stronger than that of the outer peripheral surface of the first cleaning rotational body.

It is desirable that, in the substrate cleaning apparatus, a substrate driving unit and a rotational body driving unit for rotating the substrate holding unit and the first cleaning rotational body, respectively, are installed; and a rotational number of the substrate by the substrate driving unit and a rotational number of the first cleaning rotational body by the rotational body driving unit are set so that the substrate and the first cleaning rotational body are not slid from each other. It is also desirable that, when viewed from a top, a rotational shaft of the first cleaning rotational body is extended along a diameter of a circle whose center is a rotational center of the substrate holding unit or along an extended line thereof.

The second cleaning rotational body may have an outer diameter larger than that of the first cleaning rotational body, and plural second cleaning rotational bodies may be installed as the second cleaning rotational body. Further, the plural second cleaning rotational bodies may be installed on a common holding body, and the common holding body may be configured to sequentially change the second cleaning rotational bodies making contact with the first cleaning rotational body.

Further, the substrate cleaning apparatus may further include: a reactant gas supply opening for supplying a reactant gas which reacts with a deposit adhered to the rear surface peripheral portion of the substrate; a suction opening for exhausting the reactant gas; and a supplying means for supplying a light energy or a heat energy to a region, to which the reactant gas is supplied, at the substrate. The reactant gas may be an ozone gas. It is desirable that the circular-shaped substrate is a semiconductor wafer, and the rear surface peripheral portion of the substrate includes a rear surface of a bevel portion of a periphery.

In accordance with another aspect of the present disclosure, there is provided a substrate processing apparatus for taking out a semiconductor wafer from a carrier mounted on a carrier port, through which the carrier accommodating plural sheets of semiconductor wafers is loaded and unloaded, and transferring the taken semiconductor wafer to a processing unit, and performing a gas process or a liquid process on a surface of the semiconductor wafer in the processing unit, and transferring the processed semiconductor wafer to the carrier mounted on the carrier port, and wherein the above-described substrate cleaning apparatus is installed to clean a bevel portion of a rear surface of the semiconductor wafer processed in the processing unit.

In accordance with still another aspect of the present disclosure, there is provided a substrate cleaning method including: adsorbing and holding a center portion rather than the rear surface peripheral portion of the substrate to a substrate holding unit; bringing an adhesive surface of a first cleaning rotational body, of which an outer peripheral surface is configured as the adhesive surface, into contact with the rear surface peripheral portion of the substrate; bringing an adhesive surface of a second cleaning rotational body, of which an outer peripheral surface is configured as the adhesive surface having an adhesive force stronger than that of the adhesive surface of the first cleaning rotational body, into contact with the adhesive surface of the first cleaning rotational body; and subsequently, cleaning the rear surface peripheral portion of the substrate by integrally rotating the substrate, the first cleaning rotational body and the second cleaning rotational body, and transferring a deposit adhered to the rear surface peripheral portion of the substrate to the adhesive surface of the second cleaning rotational body via the adhesive surface of the first cleaning rotational body.

Further, plural second cleaning rotational bodies are installed on a common holding body as the second cleaning rotational body, and the substrate cleaning method may further include: performing the cleaning step while bringing at least one of the plural second cleaning rotational bodies into contact with the first cleaning rotational body, and then separating said at least one of the second cleaning rotational body from the first cleaning rotational body by operating the holding body, and bringing at least another one of the second cleaning rotational bodies into contact with the first cleaning rotational body. The cleaning step may include: with respect to the rear surface peripheral portion of the substrate, supplying a reactant gas to be reacted with the deposit adhered to the rear surface peripheral portion of the substrate; exhausting the reactant gas and forming a reactant gas supplying region; and supplying a light energy or a heat energy to the supplying region.

In accordance with still another aspect of the present disclosure, there is provided a substrate processing method including: loading a carrier accommodating plural sheets of semiconductor wafers to a carrier port; taking out the semiconductor wafer from the carrier mounted on the carrier port and transferring it to a processing unit; performing a gas process or a liquid process on a surface of the semiconductor wafer in the processing unit; subsequently, performing the above-described substrate cleaning method on a bevel portion of a rear surface of the semiconductor wafer processed in the processing unit; and transferring the semiconductor wafer to the carrier after performing the cleaning method.

In accordance with still another aspect of the present disclosure, a storage medium stores a computer program executed on a computer, and the computer program is composed to execute the substrate cleaning method or the substrate processing method.

In accordance with the present disclosure, in a process of removing the deposit adhered to the rear surface peripheral portion of the circular-shaped substrate, the first and second cleaning rotational bodies and the substrate are integrally rotated by bringing the adhesive surface of the first cleaning rotational body into contact with the rear surface peripheral portion of the substrate and with the adhesive surface of the second cleaning rotational body having an adhesive force stronger than that of the first cleaning rotational body. Accordingly, the deposit adhered to the rear surface peripheral portion of the substrate is transferred to the second cleaning rotational body via the first cleaning rotational body, so that it is possible to clean the substrate and the first cleaning rotational body consecutively. Therefore, it is possible to reliably and easily remove the deposit adhered to the rear surface peripheral portion of the substrate.

### BRIEF DESCRIPTION OF THE DRAWINGS

FIG. 1 is a plan view showing an example of a substrate processing apparatus in accordance with the present invention;

FIG. 2 is a longitudinal cross-sectional view showing an example of a processing unit in the substrate processing apparatus;

FIG. 3 provides a longitudinal cross-sectional view showing an example of a substrate cleaning apparatus in accordance with the present invention;

FIG. 4 is a magnified longitudinal cross-sectional view showing a vicinity of an end portion of a substrate in the substrate cleaning apparatus;

FIGS. 5A to 5B illustrate magnified schematic views showing the vicinity of the end portion of the substrate in the substrate cleaning apparatus;

FIG. 6 is a magnified schematic view showing the vicinity of the end portion of the substrate in the substrate cleaning apparatus;

FIGS. 7A to 7D illustrate schematic views showing a cleaning process performed in the substrate cleaning apparatus;

FIGS. 8A to 8C are schematic views showing a cleaning process performed in the substrate cleaning apparatus;

FIG. 9 provides a longitudinal cross-sectional view showing another example of a second adhesive member in the substrate cleaning apparatus;

FIG. 10 is a longitudinal cross-sectional view showing another example of a second adhesive member in the substrate cleaning apparatus;

FIG. 11 provides a plan view showing another example of a first adhesive member in the substrate cleaning apparatus;

FIG. 12 is a longitudinal cross-sectional view showing another example of a first adhesive member of the substrate cleaning apparatus;

FIG. 13 is a longitudinal cross-sectional view showing another example of a first adhesive member and a second adhesive member in the substrate cleaning apparatus; and

FIG. 14 provides a longitudinal cross-sectional view showing another example of a first adhesive member in the substrate cleaning apparatus.

### DETAILED DESCRIPTION OF THE INVENTION

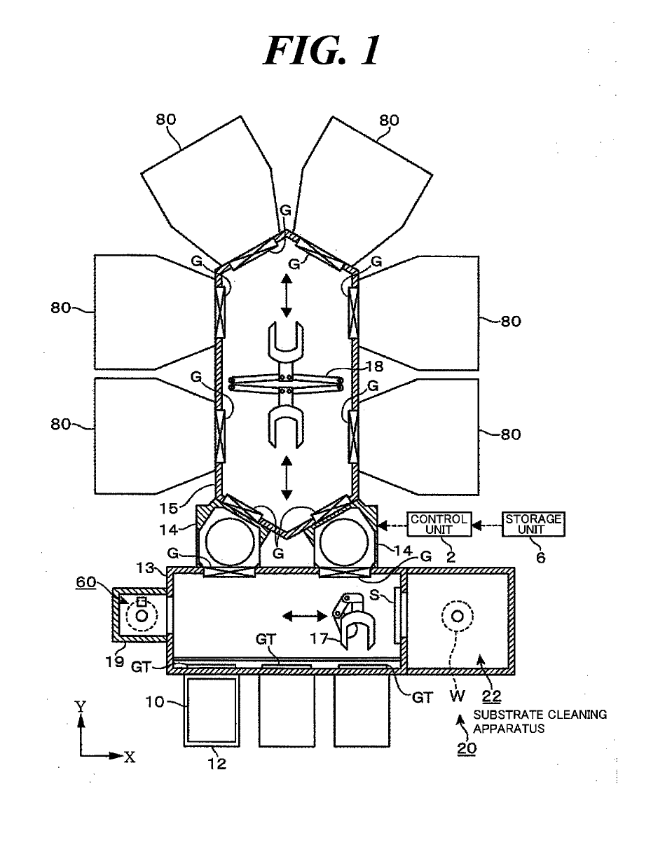

Prior to explaining embodiments of a substrate cleaning apparatus in accordance with the present disclosure, an example of a substrate processing apparatus employing the substrate cleaning apparatus will be briefly explained with reference to FIG. 1. In FIG. 1, reference numeral 12 represents a load port serving as a carrier port and reference numeral 13 represents a first transfer chamber under an atmospheric atmosphere. The load port 12 is configured to be mounted thereon with a FOUP 10 which is a sealed carrier accommodating plural sheets of circular-shaped substrate, e.g., a semiconductor wafer (hereinafter, referred to as a ‘wafer’) W, and gate doors GT opened or closed together with lids of the FOUPs 10 are installed between three load ports 12 and the first transfer chamber 13.

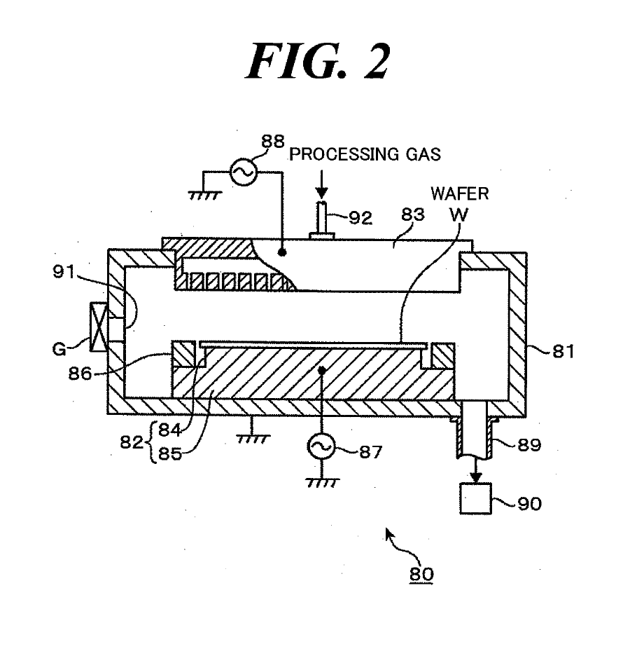

Further, an inner side of the first transfer chamber 13 is airtightly connected with a second transfer chamber 15 under a vacuum atmosphere via two load-lock chambers 14 which switch between an atmospheric atmosphere and a vacuum atmosphere. Furthermore, the second transfer chamber 15 is airtightly connected with process modules 80 which are processing units for performing plasma processes, i.e., vacuum processes such as an etching process. Further, transfer arms 17 and 18 are installed in the first transfer chamber 13 and the second transfer chamber 15, respectively. The first transfer chamber 13 is connected on left and right sides thereof with an alignment unit 19 and a substrate cleaning apparatus 20 in accordance with the present invention, respectively. As can be seen in FIG. 2, the process module 80 is configured as a plasma etching apparatus of a parallel plate type in which a mounting table 82 constituting a lower electrode and having an electrostatic adsorption function is disposed to be opposite to an upper electrode 83 constituting a gas shower head in a vacuum container 81.

The mounting table 82 includes a large diameter portion 85 in a lower part thereof and a small diameter portion 84 in an upper part thereof, and the small diameter portion 84 is configured to have a diameter slightly smaller than that of the wafer W so that the small diameter portion 84 is not contacted with a peripheral portion of a rear surface of the wafer W. On a top surface of the large diameter portion 85, i.e., at an outer peripheral of the small diameter portion 84, a ring-shaped focus ring 86 is installed so as to control the state of the plasma to be close to an outer periphery of the wafer W, e.g., so as to gather ions in the plasma near an outer periphery portion of the wafer W. Further, in FIG. 2, reference numeral 87 represents a bias power supply, reference numeral 88 represents a high frequency power supply, reference numeral 89 represents a gas exhaust pipe, reference numeral 90 represents a vacuum pump, reference numeral 91 represents a wafer transfer port, reference numeral 92 represents a processing gas supply pipe and G represents a gate.

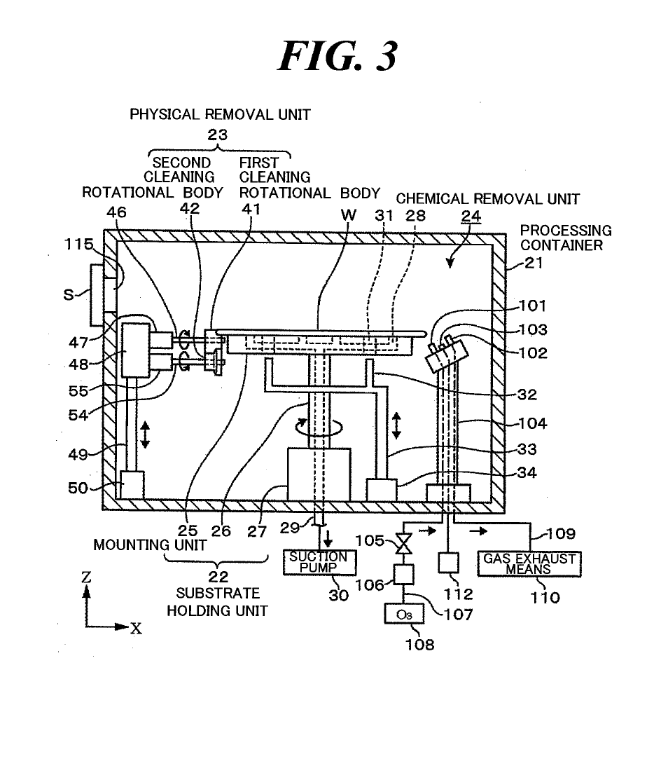

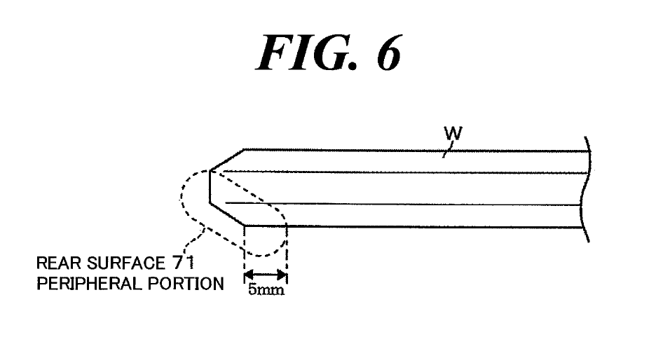

Hereinafter, the substrate cleaning apparatus 20 will be explained with reference to FIGS. 3 to 7D. The substrate cleaning apparatus 20 includes a processing container 21 under an atmospheric atmosphere; a substrate holding unit 22, which is a rotatable mounting table, installed on a center of a bottom surface of the processing container 21; a physical removal unit 23 for physically removing a deposit 75 adhered to a rear surface peripheral portion 71 of the wafer W; and a chemical removal unit 24 for chemically removing the deposit 75. The rear surface peripheral portion 71 of the wafer W, as illustrated in FIG. 6, is an area including a rear surface of a bevel portion of the peripheral portion of the wafer W, and in this example, it indicates the rear surface of the bevel portion, a side surface of the wafer W and an area of 5 mm extended from the bevel portion to an inner side.

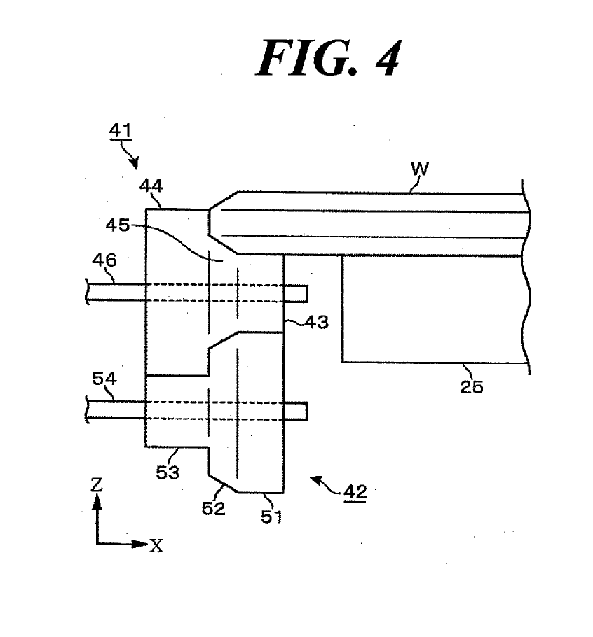

The substrate holding unit 22 includes a mounting unit 25 for supporting the wafer W from its rear surface; a rotational shaft 26 for rotating the mounting unit 25 by a rotation driving unit 27; and the rotation driving unit 27 connected with a lower portion of the rotational shaft 26. Further, the substrate holding unit 22 is configured to be rotated, for example, in a clockwise direction. The mounting unit 25 is configured to have a diameter slightly smaller than that of the wafer W. Thus, as illustrated in FIG. 4, the peripheral portion of the wafer W protrudes from a peripheral portion of the mounting unit 25 toward an outside. In a surface of the mounting unit 25, a plurality of suction holes 28 are formed so that the wafer W is adsorbed and held through the suction holes 28 by using a suction pump 30, which serves as a substrate holding apparatus, via a suction passage 29 formed to penetrate the rotational shaft 26, the rotation driving unit 27 and the bottom surface of the processing container 21. Further, through-holes 31 are formed in, for example, three places of the mounting unit 25. An elevating mechanism 34 is installed on the bottom surface of the processing container 21. For example, three elevating pins 32 are elevated by a supporting unit 33 connected to the elevating mechanism 34 via the through-holes 31, so that it is possible to perform a transfer of the wafer W to the first transfer arm 17.

The physical removal unit 23 includes a first cleaning rotational body 41 disposed on a lower side of the wafer W and a second cleaning rotational body 42 disposed on a lower side of the first cleaning rotational body 41. The first cleaning rotational body 41 is a roller having a roughly cylindrical shape and made of an adhesive material such as butyl rubber, and an outer peripheral surface thereof is configured as an adhesive surface. Further, a rotational center of the first cleaning rotational body 41 is extended horizontally and in a diametric direction of the wafer W. Furthermore, the first cleaning rotational body 41 includes a small diameter portion 43, a taper portion 45 and a large diameter portion 44 in sequence, from an inner peripheral of the wafer W toward an outer peripheral thereof, and a ring-shaped vertical surface is formed between the taper portion 45 and the large diameter portion 44. The first cleaning rotational body 41 is configured so that an outer periphery surface of the small diameter portion 43 makes contact with the peripheral portion of the rear surface of the wafer W, an outer periphery surface of the taper portion 45 makes contact with a lower side of the bevel portion, and the vertical surface makes contact with the side surface of the wafer W. Accordingly, the first cleaning rotational body 41 may be wholly brought into contact with the rear surface peripheral portion 71.

The first cleaning rotational body 41 is connected with a driving unit 47 fixed to a fixing unit 48 via a rotational shaft 46. A top surface of the first cleaning rotational body 41 is rotated according to a rotation of the wafer W in the same direction as a movement direction of the peripheral portion of the wafer W (in a direction from the front side toward the rear side of the paper in FIG. 3), and rotated so that the wafer W and the first cleaning rotational body 41 are prevented from being slid with each other. The fixing unit 48 is connected with an elevating mechanism 50 via an elevating shaft 49. The first cleaning rotational body 41 is configured to be elevated, as described above, between a cleaning position where the first cleaning rotational body 41 wholly makes contact with the rear surface peripheral portion 71 of the wafer W and a lower position where a transfer of the wafer W to the first transfer arm 17 and a process of the chemical removal unit 24 are performed, via the fixing unit 48 and the elevating shaft 49.

At a lower side of the first cleaning rotational body 41, installed is the second cleaning rotational body 42 making contact with the first cleaning rotational body 41 and having roughly the same size as the first cleaning rotational body 41. In the same manner as the first cleaning rotational body 41, the second cleaning rotational body 42 is a roller having a roughly cylindrical shape and made of an adhesive material such as butyl rubber, and an outer peripheral surface thereof is configured as an adhesive surface. Further, a rotational shaft of the second cleaning rotational body 42 is parallel to that of the first cleaning rotational body 41. With respect to a material of the second cleaning rotational body 42, e.g., the degree of polymerization and the like in butyl rubber is adjusted so that an adhesive strength of the surface of the second cleaning rotational body 42 is stronger than that of the surface of the first cleaning rotational body 41. Further, the second cleaning rotational body 42 is configured so that a diameter thereof decreases from the inner peripheral of the wafer W toward the outer peripheral thereof, and is made up of a large diameter portion 51, a taper portion 52 and a small diameter portion 53 in sequence from the inner peripheral of the wafer W. The large diameter portion 51, the taper portion 52 and the small diameter portion 53 are in contact with the small diameter portion 43, the taper portion 45 and the large diameter portion 44 of the first cleaning rotational body 41, respectively. Therefore, the second cleaning rotational body 42 wholly makes contact with the first cleaning rotational body 41.

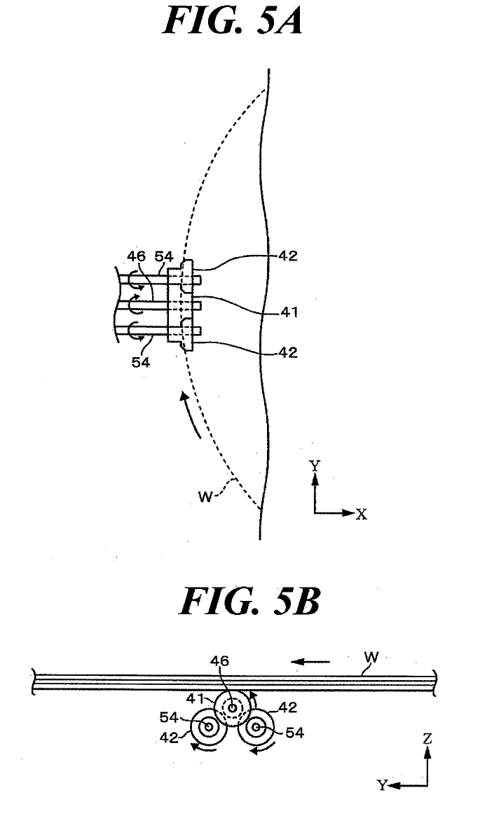

The second cleaning rotational body 42 is connected with a driving unit 55 via a rotational shaft 54, and rotated in the opposite direction of the first cleaning rotational body 41 by the driving unit 55. The driving unit 55 is fixed to the fixing unit 48 in the same manner as the driving unit 47, and configured to be integrally elevated with the driving unit 47 while the first cleaning rotational body 41 and the second cleaning rotational body 42 are in contact with each other. As illustrated in FIGS. 5A and 5B, two second cleaning rotational bodies 42 and 42 are arranged to be parallel to each other in the direction of Y axis. Further, each of two second cleaning rotational bodies 42 and 42 makes contact with the first cleaning rotational body 41 and is connected with the driving unit 55. The first cleaning rotational body 41 and the second cleaning rotational body 42 are configured to be detachable from the rotational shafts 46 and 54, respectively, so that the first cleaning rotational body 41 and the second cleaning rotational body 42 can be replaced, for example, during the maintenance.

The chemical removal unit 24 is installed close to the rear surface peripheral portion 71 of the wafer W. The chemical removal unit 24 includes a reactant gas supply opening 101 for supplying the rear surface peripheral portion 71 with a reactant gas which reacts with the deposit 75 (which will be described later); a suction opening 102 for exhausting the reactant gas supplied to the rear surface peripheral portion 71; and a light energy supplying means 103 for heating the rear surface peripheral portion 71 by irradiating a laser beam thereto. In the processing container 21, the chemical removal unit 24 is installed opposite to the physical removal unit 23. The reactant gas supply opening 101, the suction opening 102 and the light energy supplying means 103 are fixed to a bottom surface of the processing container 21 by a supporting unit 104. The reactant gas supply opening 101 is configured to supply the reactant gas, e.g., an ozone gas which is an oxidizing gas from a reactant gas source 108 through a reactant gas supply line 107 passing through the supporting unit 104 and the bottom surface of the processing container 21 and having a valve 105 and a flow rate control unit 106. Further, likewise, the suction opening 102 is configured to exhaust the reactant gas supplied to the rear surface peripheral portion 71 of the wafer W by a gas exhausting means 110 having a non-illustrated valve via a suction line 109 passing through the supporting unit 104 and the bottom surface of the processing container 21. As will be described later, an air flow region 111 where the reactant gas is supplied is formed at the rear surface peripheral portion 71 of the wafer W by the reactant gas supply opening 101 and the suction opening 102.

The light energy supplying means 103 is connected with a power supply 112 via the supporting unit 104 and the bottom surface of the processing container 21. In FIG. 3, reference numeral 115 represents a transfer port of the wafer W. The light energy supplying means 103 may provide any light besides the laser beam, or may be a means, e.g., for providing a heat energy to the rear surface peripheral portion 71 of the wafer W by using a heater.

In the substrate processing apparatus, as illustrated in FIG. 1, a control unit 2 composed of, e.g., a computer is installed. The control unit 2 includes a data processing unit composed of a program, a memory and a CPU. The program contains an instruction (each step) for performing a substrate cleaning method or a substrate processing method which will be described later by sending a control signal from the control unit 2 to each unit of the substrate processing apparatus. Further, for example, the memory has a region written with processing parameter values such as a rotational speed of the rotation driving units 27, 47 and 55, an intensity of the laser beam irradiated onto the wafer W, a pressure and a temperature when performing an etching process, which is a vacuum process, on the wafer W. When the CPU executes each instruction in the program, the processing parameter values are read out and the control signal according to the read out parameter values is sent to each unit of the substrate processing apparatus. The program (including a program for inputting or displaying the processing parameter values) is stored in a storage unit 6 of a computer storage medium such as a flexible disc, a compact disc, a hard disc, an MO (magneto-optical disc) or the like and installed in the control unit 2.

Hereinafter, an example of a substrate processing method including a substrate cleaning method carried out in the substrate processing apparatus will be explained. First, the FOUP 10 accommodating the wafer W is mounted on the load port 12 and the wafer W is transferred to a position adjusting mechanism 60 via the first transfer chamber 13 by the first transfer arm 17. In the position adjusting mechanism 60, a direction of a cutoff portion of the wafer W is adjusted by a well-known method, for example, by rotating the wafer W and irradiating a light onto the peripheral portion of the wafer W. If the wafer W is found to be eccentric, the wafer W is received by the first transfer arm 17 so as to adjust the eccentricity thereof. Then, the wafer W is transferred to the load-lock chamber 14 and subsequently, loaded into the process module 80 by the second transfer arm 18.

In the process module 80, the atmosphere in the vacuum container 81 is set to have a specific vacuum level, and the processing gas is provided to the wafer W. Then, the processing gas is converted into plasma, and the etching process is performed on the wafer W by the plasma. Since a byproduct is generated from the wafer W during the etching process, the byproduct is floated within the vacuum container 81 as a floating matter and the floating matter is introduced into the side surface or the rear surface of the wafer W from a gap between the focus ring 86 and the wafer W, thereby being adhered to the rear surface peripheral portion 71 of the wafer W as the deposit 75. After the etching process is completed, a supply of the processing gas is stopped and the inside of the vacuum container 81 is vacuum-evacuated, and the wafer W is transferred to the substrate cleaning apparatus 20 via the load-lock chamber 14 and the first transfer chamber 13 by the second transfer arm 18 and the first transfer arm 17.

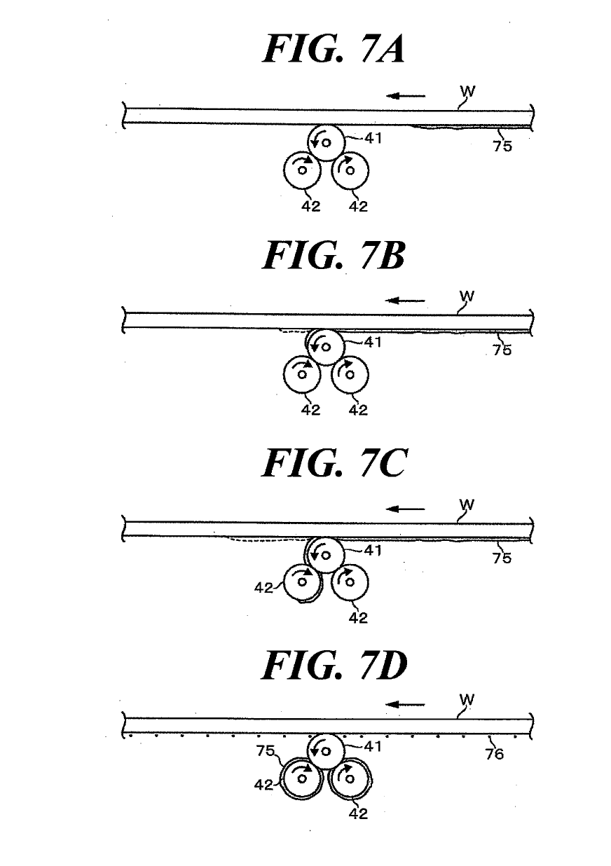

In the processing container 21, the wafer W is mounted on the substrate holding unit 22 by the elevating pins 32 to prevent the deposit 75 from being transferred to the substrate holding unit 22, and the wafer W is adsorbed and held. Then, the fixing unit 48 disposed in the lower position is elevated to the upper position so as to bring the first cleaning rotational body 41 into contact with the rear surface peripheral portion 71 of the wafer W. Subsequently, as illustrated in FIG. 7A, the wafer W is rotated, and the first cleaning rotational body 41 and the second cleaning rotational body 42 are rotated at the same peripheral speed as the wafer W. If the deposit 75 adhered to the rear surface peripheral portion 71 of the wafer W is in contact with the first cleaning rotational body 41, as illustrated in FIG. 7B, the deposit 75 is transferred from the rear surface peripheral portion 71 of the wafer W to the surface of the first cleaning rotational body 41. Then, if the deposit 75 transferred onto the first cleaning rotational body 41 makes contact with the second cleaning rotational body 42, as mentioned above, since the second cleaning rotational body 42 has a stronger adhesive force than the first cleaning rotational body 41, the deposit 75 is transferred again to the second cleaning rotational body 42 on the left side in FIG. 7B. For example, even though the deposit 75 is not transferred to the second cleaning rotational body 42 on the left side and remains in the first cleaning rotational body 41, the deposit 75 adhered to the first cleaning rotational body 41 is removed by the second cleaning rotational body 42 on the right side (see FIG. 7C).

Further, by performing the cleaning process until, for example, one rotation of the wafer W is made, the deposit 75 adhered to the rear surface peripheral portion 71 of the wafer W is removed as illustrated in FIG. 7D. Further, since the deposit 75 transferred to the first cleaning rotational body 41 is removed by the second cleaning rotational body 42, the surface of the first cleaning rotational body 41 remains clean. Further, in FIGS. 7A to 7D, for easy understanding, the deposit 75 is illustrated in large quantity and the first cleaning rotational body 41 or the second cleaning rotational body 42 is simply depicted.

However, an organic material which is a material constituting the first cleaning rotational body 41 is separated therefrom and adhered to the rear surface peripheral portion 71 because the first cleaning rotational body 41 makes contact with the rear surface peripheral portion 71 of the wafer W, or some organic material, which was unable to be removed by the first cleaning rotational body 41 because the size of the deposit 75 is too small, remains in the rear surface peripheral portion 71 of the wafer W. Therefore, a chemical process described below is performed on a residue 76 such as the organic material or the like.

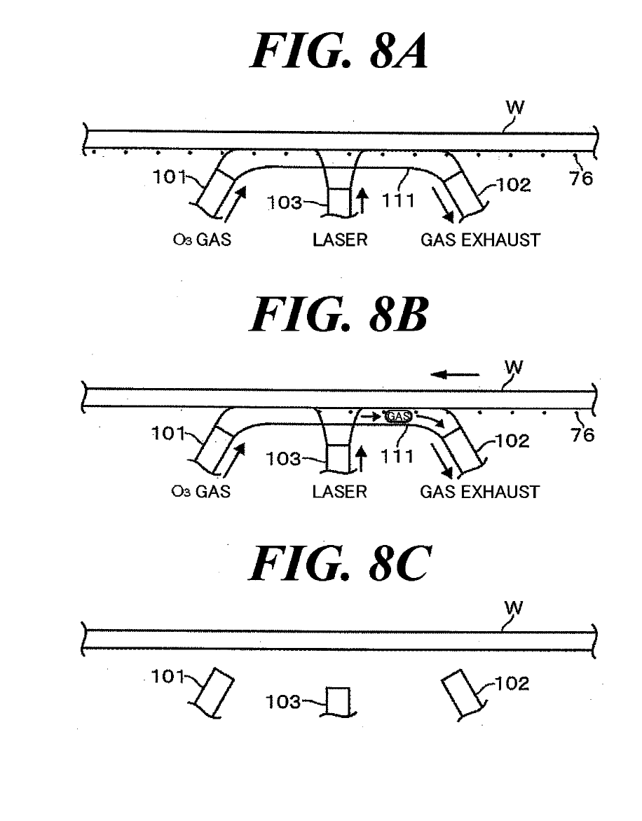

First, the rotations of the wafer W, the first cleaning rotational body 41 and the second cleaning rotational body 42 are stopped, and the fixing unit 48 is descended to the lower position. Then, as illustrated in FIG. 8A, the ozone gas is supplied from the reactant gas supply opening 101, and the ozone gas is sucked and exhausted through the suction opening 102, thereby generating the air flow region 111 of the ozone gas at the rear surface peripheral portion 71 of the wafer W. Further, the laser beam is irradiated onto the air flow region 111 and the wafer W is rotated. The residue 76 adhered to the rear surface peripheral portion 71 of the wafer W, as illustrated in FIG. 8B, is oxidized by the ozone gas and heated by the laser beam to be gasified and then exhausted together with the ozone gas through the suction opening 102. The chemical process is carried out until, for example, one rotation of the wafer W is made, so that the residue 76 adhered to the rear surface peripheral portion 71 of the wafer W is removed as illustrated in FIG. 8C. When the ozone gas is supplied to the rear surface peripheral portion 71 of the wafer W, since the reactant gas supply opening 101 and the suction opening 102 are near the rear surface peripheral portion 71 of the wafer W, the ozone gas is not introduced to the surface of the wafer W and thus have no bad effect thereon. Subsequently, the supply of the ozone gas and the irradiation of the laser beam are stopped, and also the rotation of the wafer W is stopped. Then, the wafer W is returned to the FOUP 10 by the first transfer arm 17.

In accordance with the above-described embodiments, the rear surface peripheral portion 71 of the wafer W is brought into contact with the outer peripheral surface of the first cleaning rotational body 41 having an adhesive force, and the outer peripheral surface of the first cleaning rotational body 41 is brought into contact with the outer peripheral surface of the second cleaning rotational body 42 having a stronger adhesive force than the outer peripheral surface of the first cleaning rotational body 41, and the wafer W, the first cleaning rotational body 41 and the second cleaning rotational body 42 are integrally rotated, thereby transferring the deposit 75 adhered to the rear surface peripheral portion 71 of the wafer W to the second cleaning rotational body 42 via the first cleaning rotational body 41. In this manner, it is possible to perform the cleaning process only on the rear surface peripheral portion 71 of the wafer W without having any effects on the front surface of the wafer W, so that a bad effect to the front surface of the wafer W or a re-adhesion of the deposit 75 to the inner peripheral of the rear surface of the wafer W can be suppressed. Further, since there is no stir of the deposit 75, it is possible to remove the deposit 75 without installing a local gas exhaust unit for sucking in the deposit 75 floating within the processing container 21.

In addition, since the deposit 75 transferred to the first cleaning rotational body 41 is further transferred by the second cleaning rotational body 42, the surface of the first cleaning rotational body 41 can be maintained clean. Therefore, a deterioration of the adhesive force of the first cleaning rotational body 41 due to the transfer of the deposit 75 can be suppressed. For this reason, the residual of the deposit 75 on the rear surface peripheral portion 71 can be reduced, and the cleaning process can be consecutively performed. Further, it is possible to extend a maintenance period for removing the deposit 75 adhered to the first cleaning rotational body 41. Furthermore, even if the residual of the deposit 75 or the organic material constituting the first cleaning rotational body 41 is adhered on the wafer W as the residue 76, since the chemical removal process is subsequently carried out by using the ozone gas and the laser beam, it is possible to reliably remove the deposit 75 or the residue 76.

Further, in the above-described embodiments, although the ozone gas is used as the processing gas, it is possible to properly change the processing gas to a compound gasified by the heating of the laser beam or the like depending on the composition of the residue 76. Further, if the residue 76 is not adhered on the wafer W and the deposit 75 can be removed clearly by the first cleaning rotational body 41 and the second cleaning rotational body 42, the chemical removal unit 24 may not be installed.

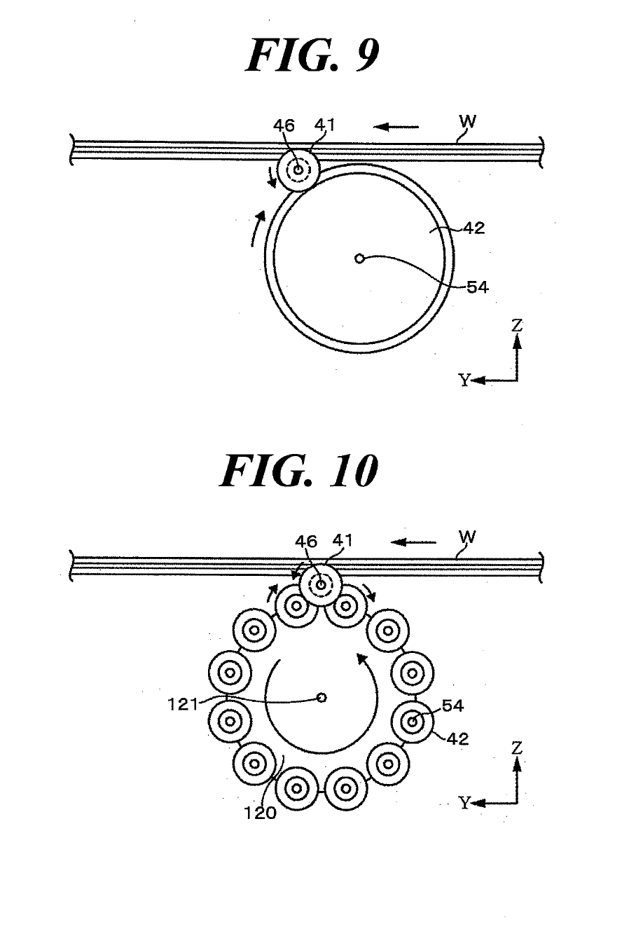

Furthermore, if a quantity of the deposit 75 is too small, only one second cleaning rotational body 42 can be installed. In addition, in the above-described embodiments, the size of the second cleaning rotational body 42 is roughly the same as that of the first cleaning rotational body 41. However, for example, as illustrated in FIG. 9, the diameter of the second cleaning rotational body 42 can be several times, e.g., two times or more larger than that of the first cleaning rotational body 41, so that the maintenance period of the first cleaning rotational body 41 can be extended. Further, by increasing the number of the second cleaning rotational body 42 making contact with the first cleaning rotational body 41 to two or more, the maintenance period can also be extended. In FIG. 9, only one second cleaning rotational body 42 is illustrated.

Furthermore, as illustrated in FIG. 10, a rotation member 120 having a large diameter can be installed parallel to the first cleaning rotational body 41 at a lower side of the first cleaning rotational body 41 as a common holding body, and plural, e.g., twelve second cleaning rotational bodies 42 which are each rotatable by the driving unit 55 may be installed on an outer peripheral portion of the rotation member 120. In this embodiment, for example, when replacing the second cleaning rotational body 42 making contact with the first cleaning rotational body 41, the rotation member 120 is brought down by a non-illustrated elevating mechanism, and the rotation member 120 is rotated by a non-illustrated motor connected to a rotational shaft 121 so that the new second cleaning rotational bodies 42 are brought into contact with the first cleaning rotational body 41 in sequence. Therefore, the maintenance period of the first cleaning rotational body 41 can be extended.

In addition, as described in each embodiment, when a length of a contact portion, in which the first cleaning rotational body 41 makes contacts with the rear surface of the wafer W, is short and thus a speed difference between a peripheral speed of the inner peripheral and a peripheral speed of the outer peripheral at the contact portion of the first cleaning rotational body 41 can be disregarded, it is possible to bring one first cleaning rotational body 41 into contact with the rear surface peripheral portion 71 of the wafer W. However, for example, if the length of the rear surface of the wafer W making contact with the first cleaning rotational body 41 is, e.g., about 50 mm and thus the speed difference is remarkable, there is a possibility that the wafer W slides from the surface of the first cleaning rotational body 41 due to such a speed difference and thus the deposit 75 is not normally removed due to such a slide movement. Therefore, it is desirable to dispose the first cleaning rotational body 41 as follows.

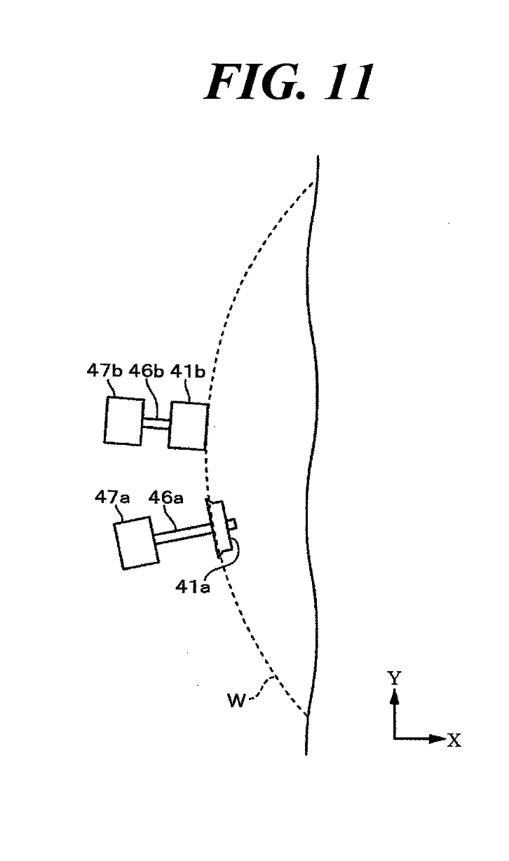

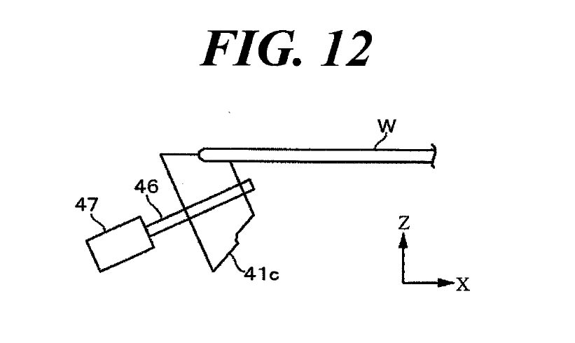

That is, for example, as illustrated in FIG. 11, the first cleaning rotational body 41 may be divided into a first cleaning rotational body 41a of an inner peripheral and a first cleaning rotational body 41b of an outer peripheral and each of the first cleaning rotational bodies 41a and 41b may be rotated by driving units 47a and 47b through rotational shafts 46a and 46b, respectively. In this case, it is desirable that the peripheral speeds of the first cleaning rotational bodies 41a and 41b coincide with the peripheral speeds of the wafer W in contact with the first cleaning rotational bodies 41a and 41b in a radial direction thereof. Further, when installing the second cleaning rotational body 42, it is desirable to install it on each of the first cleaning rotational bodies 41a and 41b. Furthermore, as shown in FIG. 12, the rotational shaft 46 of the first cleaning rotational body 41 may be inclined upward from the outer peripheral to the inner peripheral of the wafer W, and a first cleaning rotational body 41c, which has a roughly trapezoidal cross-section with a diameter being increased from the upper side toward the lower side, may be installed at the rotational shaft 46, so that the speed difference may be suppressed. In addition, though the first cleaning rotational body 41 is arranged horizontally and extended in a central direction of the wafer W, it may be arranged horizontally and inclined relative to the center of the wafer W, i.e., the direction of Y axis.

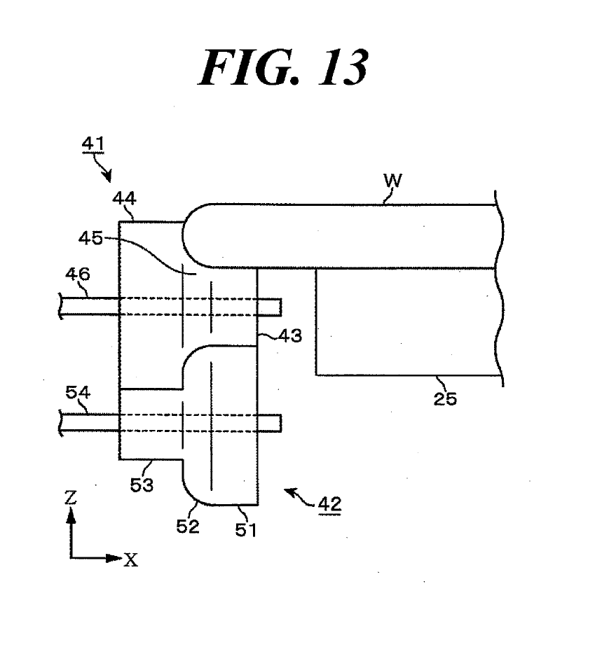

In each embodiment stated above, the shape of the end portion of the wafer W is configured to have the bevel portion by polishing it, e.g., slantingly relative to the horizontal direction as illustrated in FIG. 6. However, the shape of the end portion is not limited thereto and for example, as illustrated in FIG. 13, the side surface of the wafer W may be rounded. In this case, by allowing the outer peripheral surface of the first cleaning rotational body 41 to have a R surface, it may be brought into contact to the rear surface peripheral portion of the wafer W and the side surface thereof. Further, the shape of the second cleaning rotational body 42 may be configured to be in contact with the first cleaning rotational body 41.

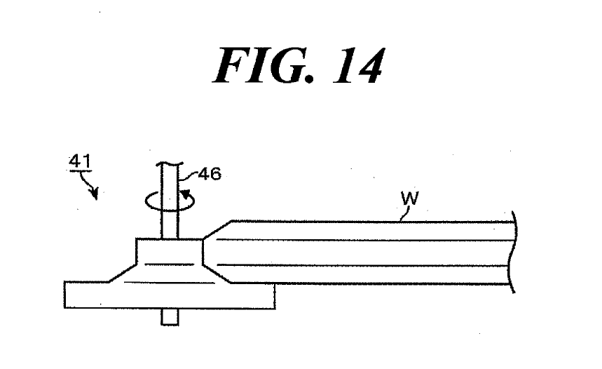

Further, in each embodiment stated above, although the first cleaning rotational body 41 and the second cleaning rotational body 42 are rotated in a horizontal direction, they may be rotated in a vertical direction as illustrated in FIG. 14. That is, the first cleaning rotational body 41 may be configured to be brought into contact with the rear surface peripheral portion 71 of the wafer W such as the bevel portion or the like. Further, in FIG. 14, though the second cleaning rotational body 42 is not shown, in this case, the second cleaning rotational body 42 may be brought into contact with the first cleaning rotational body 41, and thus the second cleaning rotational body 42 may be rotated in a horizontal direction or in a vertical direction. In each embodiment stated above, all of the first cleaning rotational body 41 and the wafer W are configured to be rotatable by installing the driving units 47 and 27. However, by applying a downward pressure to the substrate holding unit 22 or by applying an upward pressure to the first cleaning rotational body 41, e.g., through the use of a spring, it is allowed to rotate only one of the first cleaning rotational body 41 and the wafer W such that the other thereof is rotated by such a rotation.

Furthermore, the substrate cleaning apparatus in accordance with the present invention may be employed in e.g., a liquid immersion type exposure apparatus or a coating and developing apparatus as well as the substrate processing apparatus. In this case, it is used to remove a photoresist film adhered on the side surface, the bevel portion or the rear surface peripheral portion of the wafer W by a liquid immersion exposure process which is a liquid process.

What is claimed is:

1. A substrate cleaning apparatus for cleaning a rear surface peripheral portion of a circular-shaped substrate, the apparatus comprising:
a substrate holding unit, which is rotatable, for adsorbing and holding a center portion rather than the rear surface peripheral portion of the substrate and rotating a center of the substrate as a rotational center;
a first cleaning rotational body which is rotated together with the substrate while making contact with the rear surface peripheral portion of the substrate and is configured such that an outer peripheral surface thereof is an adhesive surface;
a driving unit for rotating at least one of the substrate holding unit and the first cleaning rotational body; and
a second cleaning rotational body which is rotated while making contact with the outer peripheral surface of the first cleaning rotational body and is configured such that an outer peripheral surface thereof is an adhesive surface having an adhesive force stronger than that of the outer peripheral surface of the first cleaning rotational body.

2. The substrate cleaning apparatus of claim 1, wherein a substrate driving unit and a rotational body driving unit for rotating the substrate holding unit and the first cleaning rotational body, respectively, are installed; and
a rotational number of the substrate by the substrate driving unit and a rotational number of the first cleaning rotational body by the rotational body driving unit are set so that the substrate and the first cleaning rotational body are not slid from each other.

3. The substrate cleaning apparatus of claim 1, wherein, when viewed from a top, a rotational shaft of the first cleaning rotational body is extended along a diameter of a circle whose center is a rotational center of the substrate holding unit or along an extended line thereof.

4. The substrate cleaning apparatus of claim 1, wherein the second cleaning rotational body has an outer diameter larger than that of the first cleaning rotational body.

5. The substrate cleaning apparatus of claim 1, wherein plural second cleaning rotational bodies are installed as the second cleaning rotational body.

6. The substrate cleaning apparatus of claim 5, wherein the plural second cleaning rotational bodies are installed on a common holding body, and the common holding body is configured to sequentially change the second cleaning rotational bodies making contact with the first cleaning rotational body.

7. The substrate cleaning apparatus of claim 1, further comprising:
a reactant gas supply opening for supplying a reactant gas which reacts with a deposit adhered to the rear surface peripheral portion of the substrate;
a suction opening for exhausting the reactant gas; and
a supplying means for supplying a light energy or a heat energy to a region, to which the reactant gas is supplied, at the substrate.

8. The substrate cleaning apparatus of claim 7, wherein the reactant gas is an ozone gas.

9. The substrate cleaning apparatus of claim 1, wherein the circular-shaped substrate is a semiconductor wafer, and the rear surface peripheral portion of the substrate includes a rear surface of a bevel portion of a periphery.

10. A substrate processing apparatus for taking out a semiconductor wafer from a carrier mounted on a carrier port, through which the carrier accommodating plural sheets of semiconductor wafers is loaded and unloaded, and transferring the taken semiconductor wafer to a processing unit, and performing a gas process or a liquid process on a surface of the semiconductor wafer in the processing unit, and transferring the processed semiconductor wafer to the carrier mounted on the carrier port, and
wherein a substrate cleaning apparatus as claimed in claim 9 is installed to clean a bevel portion of a rear surface of the semiconductor wafer processed in the processing unit.

11. A substrate cleaning method for cleaning a rear surface peripheral portion of a circular-shaped substrate, the method comprising:
adsorbing and holding a center portion rather than the rear surface peripheral portion of the substrate to a substrate holding unit;
bringing an adhesive surface of a first cleaning rotational body, of which an outer peripheral surface is configured as the adhesive surface, into contact with the rear surface peripheral portion of the substrate;
bringing an adhesive surface of a second cleaning rotational body, of which an outer peripheral surface is configured as the adhesive surface having an adhesive force stronger than that of the adhesive surface of the first cleaning rotational body, into contact with the adhesive surface of the first cleaning rotational body; and
subsequently, cleaning the rear surface peripheral portion of the substrate by integrally rotating the substrate, the first cleaning rotational body and the second cleaning rotational body, and transferring a deposit adhered to the rear surface peripheral portion of the substrate to the adhesive surface of the second cleaning rotational body via the adhesive surface of the first cleaning rotational body.

12. The substrate cleaning method of claim 11, wherein plural second cleaning rotational bodies are installed on a common holding body as the second cleaning rotational body, further comprising:
performing the cleaning step while bringing at least one of the plural second cleaning rotational bodies into contact with the first cleaning rotational body, and then separating said at least one of the second cleaning rotational body from the first cleaning rotational body by operating the holding body, and bringing at least another one of the second cleaning rotational bodies into contact with the first cleaning rotational body.

13. The substrate cleaning method of claim 11, wherein the cleaning step includes:
with respect to the rear surface peripheral portion of the substrate, supplying a reactant gas to be reacted with the deposit adhered to the rear surface peripheral portion of the substrate;
exhausting the reactant gas and forming a reactant gas supplying region; and
supplying a light energy or a heat energy to the supplying region.

14. The substrate cleaning method of claim 13, wherein the reactant gas is an ozone gas.

15. The substrate cleaning method of claim 11, wherein the circular-shaped substrate is a semiconductor wafer and the rear surface peripheral portion of the substrate includes a rear surface of a bevel portion of a periphery.

16. A substrate processing method, comprising:
loading a carrier accommodating plural sheets of semiconductor wafers to a carrier port;
taking out the semiconductor wafer from the carrier mounted on the carrier port and transferring it to a processing unit;
performing a gas process or a liquid process on a surface of the semiconductor wafer in the processing unit;
subsequently, performing a substrate cleaning method as claimed in claim 15 on a bevel portion of a rear surface of the semiconductor wafer processed in the processing unit; and
transferring the semiconductor wafer to the carrier after performing the cleaning method.

17. A storage medium for storing a computer program executed on a computer, wherein the computer program is composed to execute a substrate cleaning method as claimed in claim 11.
